(19) United States
(12) Patent Application Publication
(10) Pub. No.: US 2008/0237686 A1
(43) Pub. Date: Oct. 2, 2008

(54) SEMICONDUCTOR DEVICE AND METHOD FOR MANUFACTURING SEMICONDUCTOR DEVICE

(75) Inventor: Hidehiko Yabuhara, Kanagawa-ken (JP)

Correspondence Address: PEARNE & GORDON LLP, 1801 EAST 9TH STREET, SUITE 1200, CLEVELAND, OH, 44114-3108, US

(73) Assignee: KABUSHIKI KAISHA TOSHIBA, Tokyo (JP)

(21) Appl. No.: 11/859,122

(22) Filed: Sep. 21, 2007

(30) Foreign Application Priority Data
Mar. 27, 2007 (JP) 2007-081910

(51) Int. Cl. H01L 29/00; H01L 21/302

(52) U.S. Cl. 257/316; 438/704; 257/E29.129; 257/E21.214

(57) ABSTRACT

A semiconductor device includes: a control gate electrode having a first layer of polycrystalline silicon. The first layer is formed by decreasing a thickness of a first film of doped polycrystalline silicon. The first layer retains a dopant activation ratio of the first film. A method for manufacturing a semiconductor device, includes: forming a first film of doped polycrystalline silicon; and decreasing a thickness of the first film. The first film is formed by heat treating an amorphous silicon film provided on an insulating film.

### CROSS-REFERENCE TO RELATED APPLICATIONS

This application is based upon and claims the benefit of priority from the prior Japanese Patent Application No. 2007-081910, filed on Mar. 27, 2007; the entire contents of which are incorporated herein by reference.

### BACKGROUND OF THE INVENTION

1. Field of the Invention

This invention relates to a semiconductor device and a method for manufacturing a semiconductor device, and more particularly to a semiconductor device such as a semiconductor memory with its control gate electrode made of polycrystalline silicon and a method for manufacturing the same.

2. Background Art

A nonvolatile semiconductor memory device includes a floating gate electrode between a control gate electrode and a semiconductor substrate, and information is stored in the floating gate electrode by the control gate electrode. The floating gate electrode is opposed to the control gate electrode across an interlayer insulating film, and a silicon thermal oxide film is provided between the floating gate electrode and the semiconductor substrate. The control gate electrode and the floating gate electrode are made of doped polycrystalline silicon. The doped polycrystalline silicon is formed, for example, by forming a nondoped silicon film, which is subjected to doping followed by heat treatment (see, e.g., JP-A 2003-077856 (Kokai)).

With the downsizing of such a semiconductor memory device, the dimensions of the control gate electrode and the floating gate electrode are narrowed, and accordingly the distance between the control gate electrodes and the distance between the floating gate electrodes also decrease.

With such downsizing, the effect of depletion in polycrystalline silicon becomes significant, and electrical interference between adjacent floating gate electrodes increases, causing problems such as changes or variations of threshold voltage or other operating voltage (see, e.g., IEEE ELECTRON DEVICE LETTERS, VOL. 23, no. 5, May 2002, “Effects of Floating-Gate Interference on NAND Flash Memory Cell Operation”).

One of the causes of this depletion is that the decrease of dopant activation ratio (average ratio of the activated dopant concentration to the total dopant concentration) associated with the downsizing results in decrease of carriers in polycrystalline silicon. This number of carriers needs to be increased.

### SUMMARY OF THE INVENTION

According to an aspect of the invention, there is provided a semiconductor device including: a control gate electrode having a first layer of polycrystalline silicon, the first layer being formed by decreasing a thickness of a first film of doped polycrystalline silicon and retaining a dopant activation ratio of the first film.

According to another aspect of the invention, there is provided a semiconductor device including: a semiconductor substrate; an insulating film provided on the semiconductor substrate; a first layer of polycrystalline silicon provided on the insulating film; a device separation insulating film provided in a device separation trench which penetrates the insulating film and the first layer and reaches the semiconductor substrate; an interlayer insulating film provided on the first layer and the device separation insulating film; and a second layer of polycrystalline silicon provided on the interlayer insulating film, at least one of the first and second layers being formed by decreasing a thickness of a film of doped polycrystalline silicon and retaining a dopant activation ratio of the film.

According to another aspect of the invention, there is provided a method for manufacturing a semiconductor device, including: forming a first film of doped polycrystalline silicon by heat treating an amorphous silicon film provided on an insulating film; and decreasing a thickness of the first film by etching the first film.

### BRIEF DESCRIPTION OF THE DRAWINGS

FIG. 1 shows the result of simulation for the film thickness dependence of dopant activation ratio and silicon crystal grain size for polycrystalline silicon doped with phosphorus.

FIGS. 2A to 2D, 3A to 3C and 4A to 4C are cross-sectional views showing a process for manufacturing a semiconductor flash memory according to the embodiment of the invention.

### DETAILED DESCRIPTION OF THE INVENTION

An embodiment of the invention will now be described with reference to the drawings. Polycrystalline silicon constituting the control gate electrode and the floating gate electrode of a semiconductor flash memory is illustratively doped with phosphorus (P) and activated by heat treatment to generate carriers.

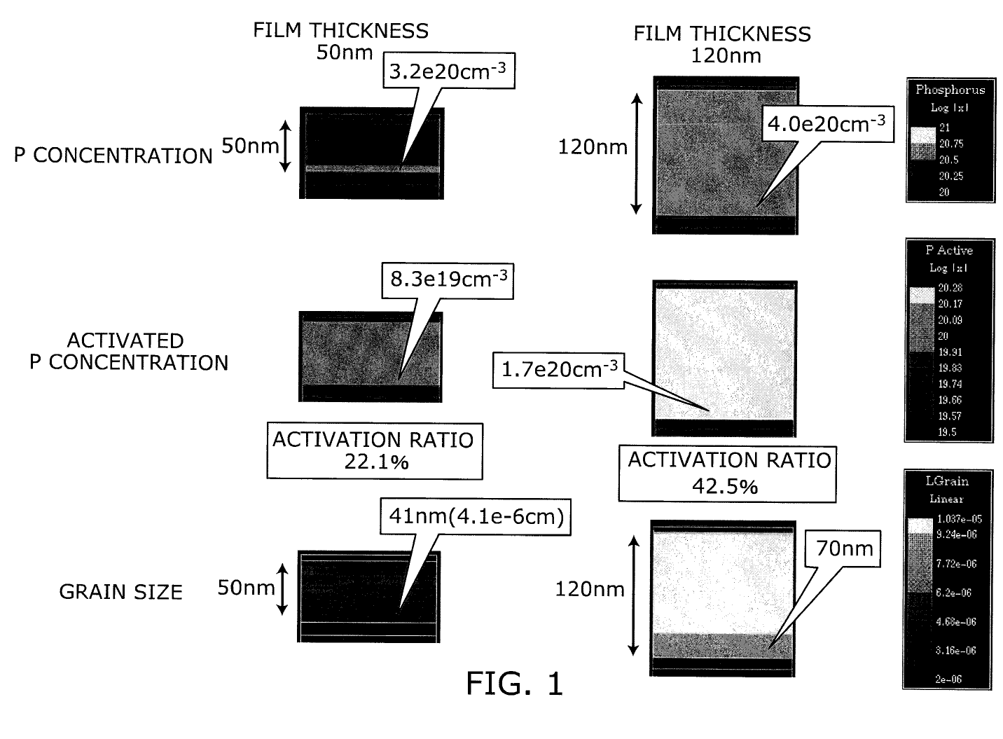

FIG. 1 shows the result of simulation for the film thickness dependence of dopant activation ratio (average ratio of activated dopant concentration to the total dopant concentration) and silicon crystal grain size for polycrystalline silicon doped with phosphorus. The dopant activation ratio used herein means the average ratio of activated dopant concentration to the total dopant concentration, and is hereinafter also referred to simply as activation ratio.

As shown in FIG. 1, in a polycrystalline silicon film having a thickness of 50 nm, near the bottom surface thereof, the total P concentration is 3.2×10²⁰ cm⁻³, and the activated P concentration is 8.3×10¹⁹ cm⁻³, yielding an activation ratio of 22.1%. The grain size of the silicon crystal is 41 nm. In contrast, in a polycrystalline silicon film having a thickness of 120 nm, near the bottom surface thereof, the total P concentration is 4.0×10²⁰ cm⁻³, and the activated P concentration is 1.7×10²⁰ cm⁻³, yielding an activation ratio of 42.5%. The grain size of the silicon crystal is 70 nm.

It turns out from FIG. 1 that the grain size of silicon crystal depends on the thickness of the polycrystalline silicon film, which results in different dopant activation ratio. That is, it turns out that the activation ratio can be increased as the film thickness is increased to increase the grain size, and that controlling (increasing) the grain size of polycrystalline silicon is effective for the increase of activation ratio. With the downsizing of the device, the thickness of the polycrystalline silicon film also decreases, and the grain size of silicon crystal accordingly decreases. This results in decreasing the activation ratio in polycrystalline silicon and carriers therein. However, the solution to this problem by simply increasing the thickness of the polycrystalline silicon film interferes with the downsizing of the device.

In the embodiment of the invention, a polycrystalline silicon film containing phosphorus (P) or other dopant is formed, and etched back to decrease the film thickness. Thus the crystal grain size and the activation ratio at the time of film formation (before etch back) is retained in the polycrystalline silicon film after etch back.

From FIG. 1, it is understood that the grain size of the polycrystalline silicon is smaller than the thickness of the polycrystalline film formed by the conventional method. In contrast, according to an embodiment of the invention, the polycrystalline silicon film is etched back, for example, until its thickness becomes smaller than the average grain size of the polycrystalline silicon thereof. Thus, a thin polycrystalline film having a large grain size and a high activation ratio can be realized. Note that “grain size” of a polycrystalline structure of a film is defined as a grain size perpendicular to a thickness direction of the film throughout this specification.

The activation ratio in polycrystalline silicon constituting the control gate electrode and the floating gate electrode of a semiconductor flash memory can be estimated by measuring electrical characteristics such as writing and reading characteristics of the device. For preventing depletion in polycrystalline silicon, the activation ratio is preferably 20% or more.

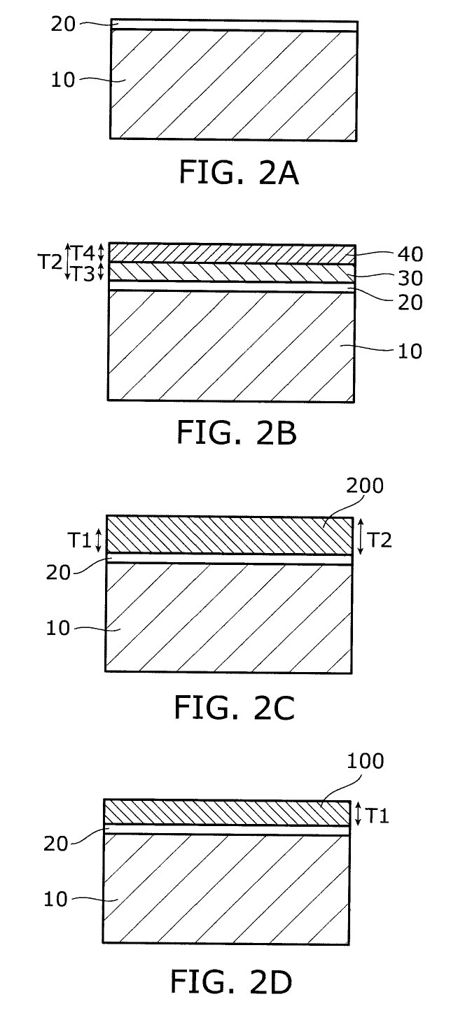

FIGS. 2A to 4C are cross-sectional views showing a process for manufacturing a semiconductor flash memory according to the embodiment of the invention. The figures primarily illustrate the process for controlling (increasing) the grain size of polycrystalline silicon. In FIGS. 2 to 4, elements similar to those described with reference to the earlier figures are marked with like reference numerals and are not described in detail.

First, as shown in FIG. 2A, a silicon thermal oxide film 20 is formed on the surface of a silicon substrate 10. The silicon thermal oxide film 20 may be turned into an oxynitride film by nitridation of its surface.

Next, a floating gate electrode is formed. As shown in FIG. 2B, on the surface of the silicon thermal oxide film 20, a dopant-free (nondoped) amorphous silicon film 30 is formed by chemical vapor deposition, and a dopant-containing (doped) amorphous silicon film 40 is formed further thereon by chemical vapor deposition. Here, phosphorus (P) is used as the dopant. At this time, the thickness of the amorphous silicon film 30 is T3, the thickness of the amorphous silicon film 40 is T4, and the total thickness of these amorphous silicon films is T2.

It is assumed herein that amorphous silicon includes completely amorphous silicon as well as microcrystalline silicon.

Next, on the surface of the amorphous silicon film 40, a cover insulating film, not shown, is formed, followed by heat treatment in a nitrogen atmosphere at 600° C. or more, for example. Then the cover insulating film is entirely peeled off by etching. This heat treatment causes solid-phase diffusion of phosphorus from the phosphorus-containing amorphous silicon film 40 of the second layer into the amorphous silicon film 30 of the first layer, and activates the dopant, phosphorus. Simultaneously, the amorphous silicon is polycrystallized. Thus, as shown in FIG. 2C, the amorphous silicon films 30, 40 are turned into a polycrystalline silicon film 200 doped with phosphorus.

This polycrystalline silicon film 200 has a thickness of T2, which is larger than the final target thickness T1. Hence, as described above with reference to FIG. 1, the grain size of silicon crystal and the activation ratio of phosphorus in the polycrystalline silicon film 200 have values corresponding to the film thickness T2, yielding a larger grain size of silicon crystal and a higher activation ratio of phosphorus than those obtained by formation of the polycrystalline silicon film 200 with target thickness T1.

Next, as shown in FIG. 2D, the polycrystalline silicon film 200 with thickness T2 is thinned by etch back from the frontside (top surface) and turned into a polycrystalline silicon film 100 with thickness T1. This etch back is performed illustratively by reactive ion etching (RIE) followed by wet etching so that the final film thickness is the target thickness T1.

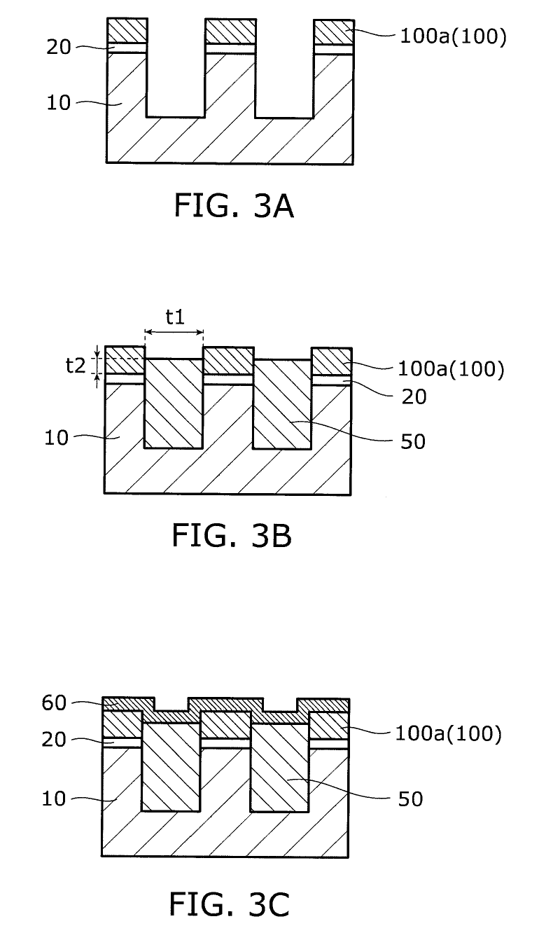

Next, as shown in FIG. 3A, the polycrystalline silicon film 100, the thermal oxide film 20, and the silicon substrate 10 are patterned by lithography and etching processes. Thus a plurality of floating gate electrodes 100a made of the polycrystalline silicon film 100 are formed, and a device separation trench is formed between the floating gate electrodes 100a. Here, the floating gate electrode 100a may be configured as a polycide structure by forming a silicide film on the polycrystalline silicon film 100 and patterning this silicide film and the polycrystalline silicon film 100.

Thus the thickness T1 of the polycrystalline silicon film 100 serving as a floating gate electrode 100a is related to the thickness T2 of the polycrystalline silicon film 200 before etch back (at the time of film formation) as:

T1<T2=T3+T4

Hence, despite its thickness T1 smaller than T2, the floating gate electrode 100a retains the grain size of silicon crystal and the activation ratio of phosphorus in the polycrystalline silicon film 200 with thickness T2. That is, it is possible to obtain a floating gate electrode 100a (polycrystalline silicon film 100) having a larger grain size of silicon crystal and a higher activation ratio of phosphorus than those obtained by formation of the polycrystalline silicon film with thickness T1. Thus, even if the polycrystalline silicon film serving as a floating gate electrode is thinned with the downsizing of the device, depletion in polycrystalline silicon can be prevented.

Next, as shown in FIG. 3B, the device separation trench is filled with a device separation insulating film 50 to form a device separation region. Here the ratio of the step dimension t2 between the surface of the floating gate electrode 100a and the surface of the device separation insulating film 50 versus the distance t1 between adjacent floating gate electrodes 100a (the width of the device separation region) is e.g. approximately 1 in accordance with the downsizing of the device.

Next, as shown in FIG. 3C, an interlayer insulating film 60 made of a high dielectric constant material (so-called high-k material) is formed on the floating gate electrode 100a and the device separation insulating film 50. The dielectric constant of the interlayer insulating film 60 is set higher than the silicon thermal oxide film, for example.

The interlayer insulating film 60 is illustratively made of a laminated film of silicon oxide film/silicon nitride film/silicon oxide film.

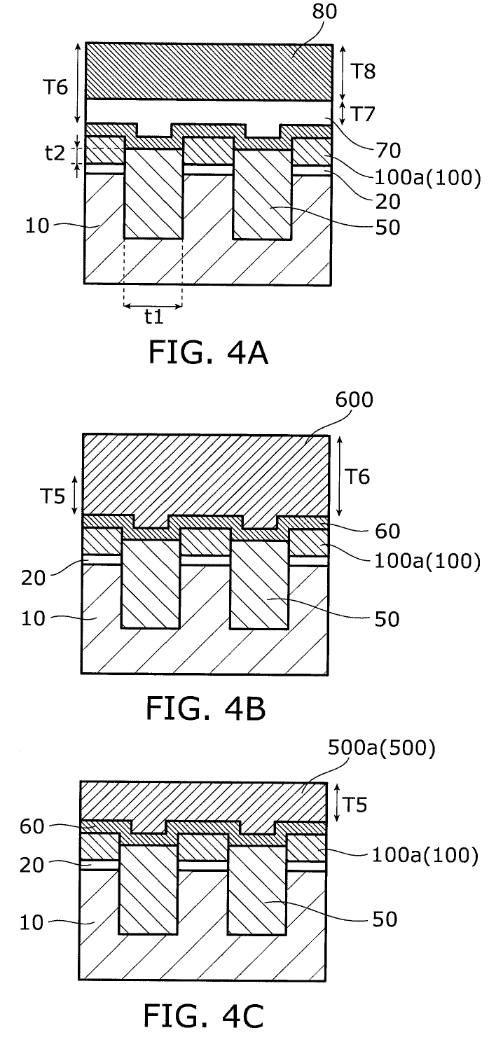

Next, a control gate electrode is formed. As shown in FIG. 4A, on the interlayer insulating film 60, a nondoped amorphous silicon film 70 is formed by chemical vapor deposition, and a doped amorphous silicon film 80 is formed further thereon by chemical vapor deposition. Here, phosphorus (P) is used as the dopant. At this time, the thickness of the amorphous silicon film 70 is T7, the thickness of the amorphous silicon film 80 is T8, and the total thickness of these amorphous silicon films is T6.

The nondoped amorphous silicon film 70 is formed so that its thickness T7 is half or more the distance between adjacent floating gate electrodes, t1. Nondoped amorphous silicon has better step coverage than doped amorphous silicon and serves to prevent voids from occurring at the step between the floating gate electrode 100a and the device separation insulating film 50. Presumably, with the downsizing of the device, the ratio of the step dimension t2 to the distance between adjacent floating gate electrodes, t1, further increases. Hence occurrence of voids can be effectively prevented by forming a nondoped amorphous silicon film in the underlying layer.

Next, on the surface of the amorphous silicon film 80, a cover insulating film, not shown, is formed, followed by heat treatment in a nitrogen atmosphere at 600° C. or more, for example. Then the cover insulating film is entirely peeled off by etching. This heat treatment causes solid-phase diffusion of phosphorus from the phosphorus-containing amorphous silicon film 80 of the second layer into the amorphous silicon film 70 of the first layer, and activates the dopant, phosphorus. Simultaneously, the amorphous silicon is polycrystallized. Thus, as shown in FIG. 4B, the amorphous silicon films 70, 80 are turned into a polycrystalline silicon film 600 doped with phosphorus.

This polycrystalline silicon film 600 has a thickness of T6, which is larger than the final target thickness T5. Hence, as described above with reference to FIG. 1, the grain size of silicon crystal and the activation ratio of phosphorus in the polycrystalline silicon film 600 have values corresponding to the film thickness T6, yielding a larger grain size of silicon crystal and a higher activation ratio of phosphorus than those obtained by formation of the polycrystalline silicon film 600 with target thickness T5.

Next, as shown in FIG. 4C, the polycrystalline silicon film 600 with thickness T6 is thinned by etch back from the frontside (top surface) and turned into a polycrystalline silicon film 500 with thickness T5. This etch back is performed illustratively by RIE followed by wet etching so that the final film thickness is the target thickness T5.

Then the polycrystalline silicon film 500 is patterned by lithography and etching processes. Thus a plurality of control gate electrodes 500a made of the polycrystalline silicon film 500 are formed. Here, the control gate electrode 500a may be configured as a polycide structure by forming a silicide film on the polycrystalline silicon film 500 and patterning this silicide film and the polycrystalline silicon film 500.

Thus the thickness T5 of the polycrystalline silicon film 500 serving as a control gate electrode 500a is related to the thickness T6 of the polycrystalline silicon film 600 before etch back (at the time of film formation) as:

T5<T6=T7+T8

Hence, despite its thickness T5 smaller than T6, the control gate electrode 500a retains the grain size of silicon crystal and the activation ratio of phosphorus in the polycrystalline silicon film 600 with thickness T6. That is, it is possible to obtain a control gate electrode 500a (polycrystalline silicon film 500) having a larger grain size of silicon crystal and a higher activation ratio of phosphorus than those obtained by formation of the polycrystalline silicon film with thickness T5. Thus, even if the polycrystalline silicon film serving as a control gate electrode is thinned with the downsizing of the device, depletion in polycrystalline silicon can be prevented.

The control gate electrode 500a is formed on the recess (step) produced by the floating gate electrode 100a and the device separation insulating film 50. Depletion of polycrystalline silicon prominently occurs in this recess. Hence the effect of preventing depletion according to this embodiment is manifested more prominently in the floating gate electrode formed on the step than in the control gate electrode formed on the flat portion.

As described above, according to the embodiment of the invention, it is possible to increase the grain size of silicon crystal and the dopant activation ratio even if the polycrystalline silicon film constituting the floating gate electrode and the control gate electrode is thinned. Hence depletion of polycrystalline silicon can be prevented. Thus, despite the downsizing of the device, electrical interference between adjacent floating gate electrodes can be reduced, and changes or variations of threshold voltage or other operating voltage can be restrained.

In the above embodiment of the invention, a doped amorphous silicon film is formed on a nondoped amorphous silicon film, followed by heat treatment to cause solid-phase diffusion of dopant from the overlying layer into the underlying layer for activating the dopant, along with polycrystallizing the amorphous silicon. Thus a doped polycrystalline silicon film is formed. However, the following method can be also used as the process for forming such a doped polycrystalline silicon film.

A nondoped amorphous silicon film is formed by chemical vapor deposition, followed by heat treatment in a dopant-containing gas to cause gas-phase diffusion of dopant for activating the dopant, along with polycrystallizing the amorphous silicon. Thus a doped polycrystalline silicon film can be formed. In this case, dopant may be attached from gas phase to the surface of the nondoped amorphous silicon film, followed by the above heat treatment.

Alternatively, a doped amorphous silicon film is formed by chemical vapor deposition, followed by heat treatment to cause gas-phase diffusion of dopant for activating the dopant, along with crystal growth of amorphous silicon. Thus a doped polycrystalline silicon film can be formed.

The above embodiment of the invention is illustrated with reference to a semiconductor flash memory. However, the examples of the invention can be suitably modified without departing from the spirit of the invention. The invention is applicable to semiconductor memory devices with control gate electrodes of polycrystalline silicon. Besides semiconductor memory devices, the invention is also applicable to semiconductor logic circuit devices and semiconductor arithmetic circuit devices. Likewise, the method for manufacturing a semiconductor memory device according to the invention is applicable to methods for manufacturing a semiconductor memory device, semiconductor logic circuit device, or semiconductor arithmetic circuit device by forming a polycrystalline silicon film.

1. A semiconductor device comprising:
a control gate electrode having a first layer of polycrystalline silicon,
the first layer being formed by decreasing a thickness of a first film of doped polycrystalline silicon and retaining a dopant activation ratio of the first film.

2. The semiconductor device according to claim 1, wherein the dopant activation ratio of the first layer is 20% or more.

3. The semiconductor device according to claim 1, further comprising:
a floating gate electrode having a second layer of polycrystalline silicon with an interlayer insulating film being interposed between the control gate electrode and the floating gate electrode,
wherein the second layer is formed by decreasing a thickness of a second film of doped polycrystalline silicon and retains a dopant activation ratio of the second film.

4. The semiconductor device according to claim 3, further comprising:
an interlayer insulating film between the control gate electrode and the floating gate electrode,
wherein the interlayer insulating film has a higher relative dielectric constant than silicon thermal oxide film.

5. The semiconductor device according to claim 1, wherein the control gate electrode has a polycide structure based on the first layer.

6. The semiconductor device according to claim 1, wherein an average grain size of the polycrystalline silicon of the first layer is greater than the thickness of the first layer.

7. The semiconductor device according to claim 1, wherein the first film is formed by heat treating an amorphous silicon film.

8. A semiconductor device comprising:
a semiconductor substrate;
an insulating film provided on the semiconductor substrate;
a first layer of polycrystalline silicon provided on the insulating film;
a device separation insulating film provided in a device separation trench which penetrates the insulating film and the first layer and reaches the semiconductor substrate;
an interlayer insulating film provided on the first layer and the device separation insulating film; and
a second layer of polycrystalline silicon provided on the interlayer insulating film,
at least one of the first and second layers being formed by decreasing a thickness of a film of doped polycrystalline silicon and retaining a dopant activation ratio of the film.

9. The semiconductor device according to claim 8, wherein the dopant activation ratio of at least one of the first and the second layers is 20% or more.

10. The semiconductor device according to claim 8, wherein the interlayer insulating film has a higher relative dielectric constant than silicon thermal oxide film.

11. The semiconductor device according to claim 8, further comprising a silicide film provided on the second layer.

12. The semiconductor device according to claim 8, wherein an average grain size of the polycrystalline silicon of the one of the first and second layers is greater than the thickness of the one.

13. The semiconductor device according to claim 8, wherein the film is formed by heat treating an amorphous silicon film.

14. A method for manufacturing a semiconductor device, comprising:
forming a first film of doped polycrystalline silicon by heat treating an amorphous silicon film provided on an insulating film; and
decreasing a thickness of the first film by etching the first film.

15. The method for manufacturing a semiconductor device according to claim 14, wherein the forming a first film includes forming a substantially nondoped amorphous silicon film, and forming a doped amorphous silicon film thereon, and heat treating the amorphous silicon films.

16. The method for manufacturing a semiconductor device according to claim 14, wherein the forming a first film includes forming a substantially nondoped amorphous silicon film, and heat treating the amorphous silicon film in a dopant-containing gas.

17. The method for manufacturing a semiconductor device according to claim 14, wherein the forming a first film includes forming a doped amorphous silicon film, and heat treating the amorphous silicon film.

18. The method for manufacturing a semiconductor device according to claim 14, wherein the decreasing the thickness of the first film until the thickness becomes smaller than an average grain size of the polycrystalline silicon.

19. The method for manufacturing a semiconductor device according to claim 14, wherein the decreasing the thickness of the first film includes etching by a reactive ion etching and etching by a wet etching.

20. The method for manufacturing a semiconductor device according to claim 14, wherein the amorphous silicon film includes microcrystalline silicon.
